(19) United States
(12) Patent Application Publication
(10) Pub. No.: US 2010/0023534 A1
(43) Pub. Date: Jan. 28, 2010

(54) Computer-aided safety logic certification

(75) Inventors: Jing Liu, Troy, MI (US); Chengyin Yuan, Rochester Hills, MI (US); Fangming Gu, Rochester Hills, MI (US); Stephan R. Biller, Birmingham, MI (US); Jerome O. Schroeder, Romeo, MI (US); Richard C. Immers, Rochester Hills, MI (US); Jeffrey J. Byrnes, Lake Orion, MI (US)

Correspondence Address: MacMillan, Sobanski & Todd, LLC;One Maritime Plaza, 720 Water Street, 5th Floor, Toledo, OH, 43604, US

(73) Assignee: GM GLOBAL TECHNOLOGY OPERATIONS, INC., Detroit, MI (US)

(21) Appl. No.: 12/179,640

(22) Filed: Jul. 25, 2008

(51) Int. Cl. G01R 31/3177; G06F 11/25; G06F 17/30

(52) U.S. Cl. 707/100; 714/735; 714/E11.155; 707/E17.044

(57) ABSTRACT

A method is provided for certifying safety logic code in a manufacturing automation system. A plurality of safety related test scenarios is provided for testing the safety logic code in the manufacturing automation system. A processing unit is configured for communication with the logic controller. The processing unit generates logic input signals in response to the plurality of safety related test scenarios and provides the logic input signals to the logic controller. Execution of the plurality of safety related test scenarios via the safety logic code is triggered in response to the processing unit providing the logic input signals to the logic controller. Response output signals are generated by the logic controller in response to the safety related test scenarios being executed by the safety logic code. Compliancy of the safety logic code is determined by evaluating response output signals and associated logic input signals to a predetermined standard.

### BACKGROUND OF INVENTION

The present invention relates generally to an automated safety logic certification process.

Manufacturing automation systems include the use of logic controllers for controlling safety related events in an automation process. Conventional testing and certification of the programmable safety logic algorithms in the logic controller has been performed as a manual process. The manual process involves either setting up an actual physical assembly/manufacturing line or a physical proto-type test bed that includes the physical hardware. To certify the safety programming of the logic controller, a series of test scenarios are executed by an individual who manually manipulates respective switches and sensors according to the respective routines for generating the desired input signals to the logic controller. The resulting output response signals from the logic controller are printed via a screen dump (i.e., screen printing) at a remote personal computer. The results are then manually written down in tables. The individual recording the responses manually compares the written down results with the design specifications of the manufacturing automation system. This individual then determines a pass/fail condition for each safety related test scenario for certifying the safety logic code. This procedure is repeated until all the safety related test scenarios have been tested and results obtained.

Creating physical proto-type test beds requires physical hardware, facilities, and manpower. The set-up of the hardware and the testing process is not only costly but labor intensive and time consuming. Moreover, the test results are manually recorded, manually input into a table, and then manually compared to the design specification to determine a pass/fail condition. The manual translation of data and manual certification by the individual certifying the results is susceptible to errors through the manual transfer of data or incorrect interpretation of the results.

### SUMMARY OF INVENTION

An advantage of an embodiment provides for decreased cost and increased efficiency when testing the safety logic code for a manufacturing automation system. Additional advantages include test repeatability improvements, and minimizing errors in the testing and certification process by reducing the involvement of the individual conducting the certification test which eliminates the manual input of the test signals and the manual recordation of test results.

An embodiment contemplates a method of certifying safety logic code in a manufacturing automation system having a logic controller. The logic controller receives logic input signals for executing safety logic code and outputting output response signals in response to the execution of the safety logic code. A plurality of safety related test scenarios is provided for testing the safety logic code in the manufacturing automation system. A processing unit is configured for communication with the logic controller. The processing unit generates logic input signals in response to the plurality of safety related test scenarios. The processing unit provides the logic input signals to the logic controller. The logic input signals are representative of respective signals output by safety devices in the manufacturing automation system. Execution of the plurality of safety related test scenarios via the safety logic code is triggered in response to the processing unit providing the logic input signals to the logic controller. The response output signals are generated by the logic controller in response to the safety related test scenarios being executed by the safety logic code. Each of the response output signals is representative of signals output from the logic controller to respective actuators in the manufacturing automation system. Compliancy of the safety logic code is determined by evaluating response output signals and associated logic input signals to a predetermined standard.

An embodiment contemplates a computer-aided safety logic certification system that is provided for certifying safety logic code in a manufacturing automation system. A logic controller executes safety related test scenarios via the safety logic code in the manufacturing automation system. The logic controller generates response output signals in response to executing the safety related test scenarios. A processing unit is configured to communicate with the logic controller. The processing unit generates logic input signals and selectively provides the logic input signals to the logic controller for executing the safety related test scenarios via safety logic code. A certification program determines a compliancy of the safety logic code by evaluating response output signals and associated logic input signals with a predetermined standard.

An embodiment contemplates a method of certifying safety logic in a manufacturing automated system having a logic controller for controlling safety functions. The logic controller receives logic input signals and outputs output response signals. A test script is provided. A plurality of safety related test scenarios are generated for testing safety logic code in the logic controller. The plurality of safety related test scenarios is generated by a test scenario generator based on the test script. A test-bed is assembled for generating input signals relating to the operation of the manufacturing automation system. The test bed includes at least one hardware device for generating the input signals to a processing unit. The at least one hardware device is representative of respective devices in a respective manufacturing automation system. A processing unit is configured for communication with the logic controller. The processing unit receives the safety related test scenarios from the test scenario generator and the input signals from the test bed for generating the logic input signals. The logic input signals are provided from the processing unit to the logic controller. The execution of the plurality of safety related test scenarios via the safety logic code is triggered in response to the logic input signals being provided from the processing unit to the logic controller. The response output signals are generated by the logic controller in response to the safety related test scenarios being executed by the safety logic code. Each of the response output signals is representative of signals output from the logic controller to respective actuators in the manufacturing automation system. The response output signals and associated input logic signals are recorded in a compiler. A compliancy of the safety logic code is determined by evaluating response output signals and associated input logic signals to a predetermined standard.

### BRIEF DESCRIPTION OF DRAWINGS

FIG. 1 is a schematic of a prior art manufacturing automation system.

FIG. 2 is a block diagram of a safety logic certification system according to an embodiment.

FIG. 3 is a block diagram of a test script according to an embodiment.

FIG. 4 is a tree diagram of a test scenario according to an embodiment.

FIG. 5 is a flowchart of a method for a safety logic certification routine according to an embodiment.

### DETAILED DESCRIPTION

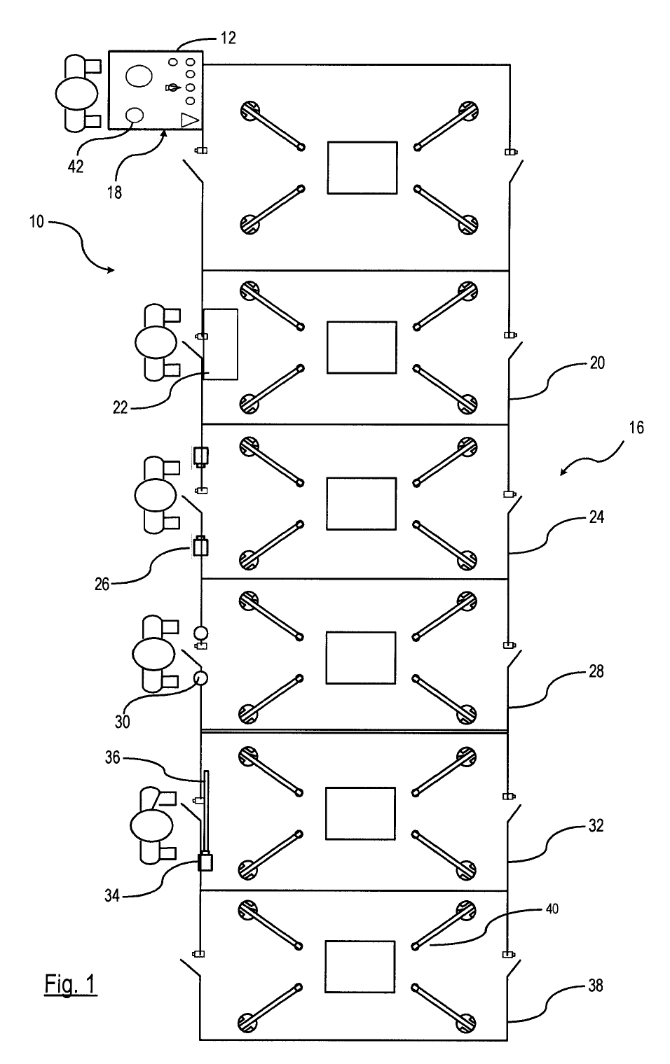

There is shown generally in FIG. 1 a manufacturing automation system 10 for assembling/manufacturing components to produce a final product. It should be understood that the manufacturing automation system 10 as illustrated in FIG. 1 is for illustrative purposes only and is not limited to an assembly/manufacturing process, but includes any manufacturing automation system incorporating safety logic. Examples include, but are not limited to, assembly operations, robot welding cells, paint stations, automatic press operations, automatic packaging, automatic cutter of printing operations, and machining centers. The manufacturing automation system 10 is controlled by a logic controller 12. The logic controller includes a primary processor and may further include a secondary processor. The logic controller 12 controls the standard and safety related functions of the manufacturing automation system 10.

The manufacturing automation system 10 includes a plurality of workstations 16 such as work cells. The workstations may involve an operator or may involve a robotic operation not requiring any assistance by an operator. The control and execution of processing the safety related functions at each of the workstations and safety related devices throughout the manufacturing automation system is controlled by the logic controller 12 housed within an electrical distribution cabinet 18.

A plurality of sensors disposed throughout the manufacturing automation system 10 provides the status of safety related events at each of the workstations. Safety related events take into consideration a variety of conditions including the safety of the operator, the machinery, and the product.

The following are only a few examples of safety related devices for monitoring safety related conditions that may be used in the manufacturing automation system. It should be understood that the workstations and safety devices described herein are not inclusive but are provided as only some examples of safety devices utilized in the manufacturing automation system 10. A first workstation 20 includes a sensed floor mat 22 for detecting whether a respective operator is standing on or off the floor mat 22 which places the operator an acceptable distance form the workstation while the operation is performed. Workstation 24 includes a light curtain sensor 26 which includes an emitter and a receiver for detecting an object breaking the sensed signal which signifies the object may be intruding into the workstation 24. Workstation 28 includes a pair of push buttons 30 for determining whether the operator's hands are free of the workstation operation. Workstation 32 includes a gate switch 34 which detects whether a gate/shield 36 providing access to the machinery of the workstation 32 is closed for shielding the operator during the operation. Workstation 38 includes an automated robot 40 having sensors for determining that the product is being processed properly by the robot.

Emergency stop buttons, such as that shown generally at 42, may be disposed throughout the manufacturing automation system 10 for manual actuation by an operator in the event an emergency condition exists requiring the manufacturing automation system to be immediately de-powered in a sequential order. For example, if an emergency button is depressed, safety standard and specifications dictates that the power in the manufacturing automation system is powered off in a safe manner.

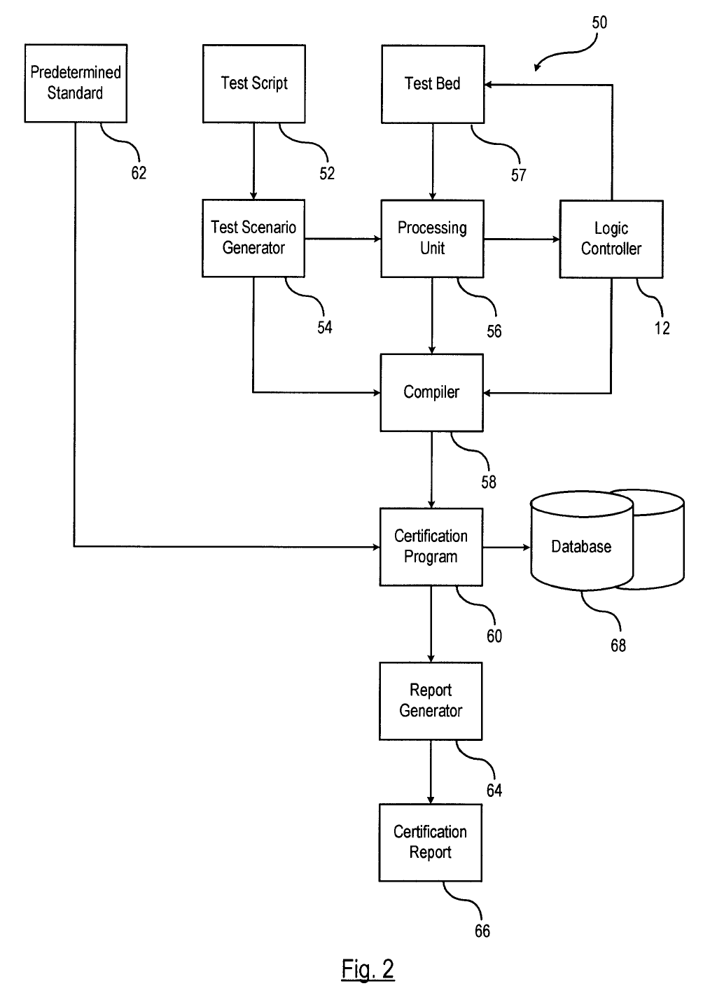

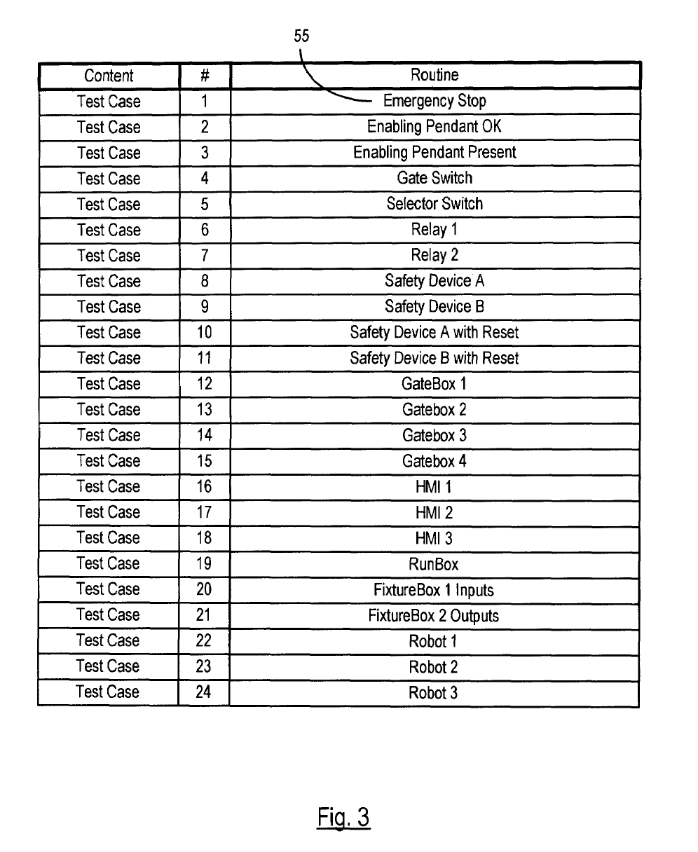

FIG. 2 illustrates a safety logic certification system 50 according to a preferred embodiment. A test script 52, also shown in detail in FIG. 3, contains a list of test cases that relate to the testing of safety related devices, switches, modules, human machine interfaces and other safety related equipment that require testing for safety logic code certification. Each of the test cases shown in FIG. 3 is identified by routine name.

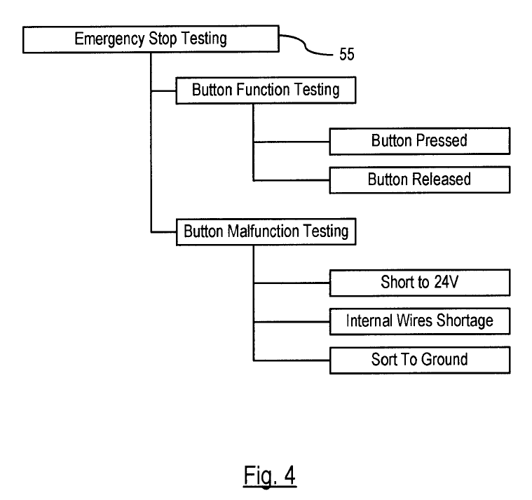

Referring again to FIG. 2, the safety logic certification system 50 includes a test scenario generator 54. The test scenario generator 54 generates a series of detailed executable safety related test scenarios for each test case provided by the test script 52. An example of a tree diagram for a respective safety related test scenario is shown generally in FIG. 4. For each safety related test scenario, a plurality of logic input signals are generated for testing the safety logic code via the logic controller 12. For example, for the test case identified as the emergency stop routine 55, the test scenario generator 54 will generate a plurality of executable detailed test scenarios for testing the emergency stop routine. Examples of the plurality of scenarios for the emergency stop routine include, but are not limited to, press emergency stop button, release emergency stop button, short-to-voltage when the emergency button is pressed, and maintain short-to-voltage when the emergency button is released.

The test scenario generator 54 is in communication with a processing unit 56. The test scenario generator 54 may be a module separate from processing unit 56 or may be integrated as a software program within the processing unit 56. The safety related test scenarios are provided to the processing unit 56. The processing unit 56 may be a computer or similar device. The processing unit 56 generates the logic input signals for executing the safety related test scenarios via the safety logic code.

The safety logic certification system 50 further includes a test bed 57. The test bed 57 includes at least one hardware device for generating input signals relating to operational characteristics of the manufacturing automation system. Each respective hardware device of the test bed 57 is representative of a respective manufacturing/assembly related device used in the manufacturing automation system. During a typical manufacturing operation, the respective hardware device performs an operation that generates input signals that are provided to the logic controller 12. The logic controller 12 generates a response output signal based on the logic input signals executed by the safety logic code. The test bed 57 reduces the complexity of having to simulate the operations of the hardware devices by the test scenario generator 54. That is, the test bed 57 generates those respective input signals that would typically be generated by the manufacturing equipment that are provided to the logic controller 12 during a respective manufacturing operation. In addition, the safety related test scenarios generated by the test scenario generator 54 for generating the respective input signals related to safety operations override the manufacturing operations executed by the test bed 57 for testing safety related functions of the manufacturing automation system. In an alternative embodiment, the test bed 57 may be entirely software-based or may be a combination of software and hardware for simulating the normal manufacturing operations of the manufacturing automation system. Moreover, for a respective test bed that is entirely software-based, each of the modules (i.e., the test bed, the test scenario generator, and the processing unit) may be integrated as a single unit.

The processing unit 54 is in communication with the logic controller 12. The processing unit 54 generates safety related input logic signals in response to the test scenarios. The safety related input logic signals are merged with the non-safety input signals from the test bed 57 and are provided to the logic controller 12 for testing the safety related test scenario via the safety logic code.

In response to the safety related logic input signals and non-safety related input signals provided by the processing unit 54, the logic controller 12 executes a respective safety related test scenario via the safety logic code and outputs the respective output response signal(s). The respective output response signals are typically a binary logic signal for commanding a safety related action to be taken by one or more actuators in the manufacturing automation system. Based on the respective output response signals, the safety logic certification system 50 can determine what the response is of the logic controller 12 for a respective safety related test scenario without having the entire equipment of the manufacturing automation system fully installed and operational or having an individual manually trigger the respective devices in a sequential order for executing a respective safety related test scenario.

A compiler 58 such as a data logger or similar device is coupled to the logic controller 12 for compiling the data output by the logic controller 12. The data includes the response output signals generated by the logic controller 12. The compiler 58 in addition to compiling the response output signals from the logic controller 12 also compiles and maps the output response signals to their associated logic input signals.

A certification program 60 compares the response output signals and associated logic input signals to a predetermined standard 62 (e.g., safety standard and specification) for determining a pass/fail condition for each of the safety related test scenarios. It should be noted that the response output signals as output by the logic controller 12 may not be directly comparable to the predetermined standard, and as a result, either the response output signals or the predetermined standard may require formatting so that a comparison between the response output signal and the predetermined standard may be performed. If the response output signals and associated logic input signals for a respective safety related test scenario are in compliance with the predetermined standard 62, the certification program 60 will identify the respective safety related test scenario as a pass condition, otherwise if not in compliance with the predetermined standard 62, the respective safety related test scenario will be identified as a fail condition. The certification program 60 alleviates an individual of having to manually compare the output response signals with the predetermined standard 62.

A report generator 64 generates a certification report 66 in response to the certification program 60 determining a pass/fail status of each safety related test scenario. The certification report 66 provides a detailed and organized summary of whether each safety related test scenario received a pass or fail condition.

A database 68 is provided for storing the results generated by the certification program 60 for future reference. The stored results include the mapped output response signals and logic input signals. The database 68 may include a computer system's fixed/removable disk drive, RAM, flash memory, network attached storage server, or any other storage medium.

As discussed earlier, known processes to certify the safety logic code have utilized a manual process involving a technician or certification specialist manually actuating the sensor devices according to a testing procedure and recording the response outputs signals. This individual thereafter manually compares the results to a predetermined standard. As a result of this manual process, only single routine testing may occur as opposed to testing multiple interactive safety routines. Time dependent testing is not possible through the manual testing process as this manual testing process only supports steady state testing. Furthermore, a large number of test scenarios is cumbersome for a single person to perform and the repeatability of the test is not guaranteed since the testing is based on the technician triggering the correct safety devices. The automated safety logic certification system minimizes the chance of errors occurring by eliminating manual operations that involve manually actuating the sensor devices, manually compiling the output response signals, manually comparing the test results, and manually generating a report for the results.

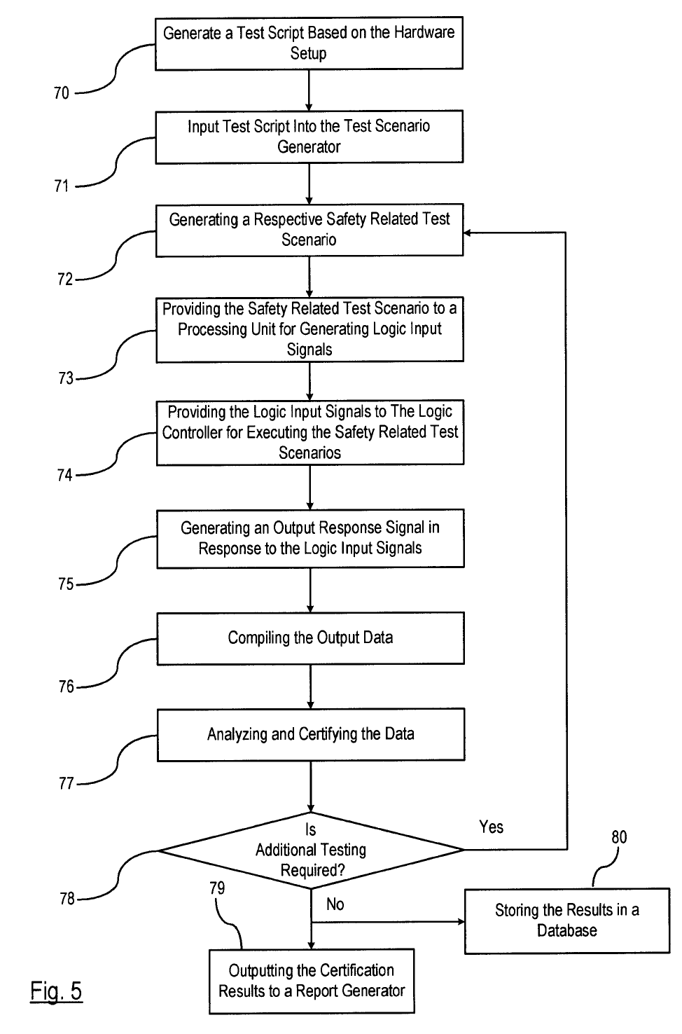

FIG. 5 illustrates a method for certifying safety logic in an automation assembly process. In step 70, a test script is generated based on the safety related devices and their associated logic programming that requires certification. In step 71, the test script is input into the scenario generator. In step 72, the scenario generator generates a respective safety related test scenario.

In step 73, the safety related test scenario is provided to a processing unit. In addition, if a test bed is utilized, the non-safety related signals generated by the respective hardware devices of the test bed are provided to the processing unit. The processing unit generates safety related logic input signals in response to the test scenarios. The non-safety input signals and the safety related input signals are merged for generating an executable safety related test scenario that may be executed by the logic controller.

In step 74, the non-safety and safety related logic input signals from the processing unit are provided to the logic controller for executing the safety related test scenarios via the safety logic code. In step 75, the logic controller generates a response output signal in response to the respective logic input signals.

In step 76, a compiler compiles the respective response output signals and the associated logic input signals. In step 77, the certification program analyzes the compiled data and determines whether the mapped response output signals and associated logic input signals for a respective safety related test scenario is in compliance with the predetermined standard. A pass condition will be identified with the safety related test scenario in response to the response output signal being in compliance with the predetermined standard. A fail condition will be identified with the safety related test scenario in response to the response output signals not being in compliance with the predetermined standard.

In step 78, a determination is made whether an additional safety related test scenario requires processing. If the determination is that there is an additional safety related test scenario to be tested, a return is made to step 72 for processing a next safety related test scenario. If the determination is made that there are no additional safety related test scenarios for processing, then the process advances to step 79.

In step 79, the results are provided to a report generator for generating a report that provides a summary of the safety related test scenarios and the pass/fail condition of each safety related test scenario. In step 80, the results are also provided to a storage device for future reference.

While certain embodiments of the present invention have been described in detail, those familiar with the art to which this invention relates will recognize various alternative designs and embodiments for practicing the invention as defined by the following claims.

What is claimed is:

1. A method of certifying safety logic code in a manufacturing automation system having a logic controller, the logic controller receiving logic input signals for executing safety logic code and outputting output response signals in response to the execution of the safety logic code, the method comprising the steps of:
(a) providing a plurality of safety related test scenarios for testing the safety logic code in the manufacturing automation system;
(b) configuring a processing unit for communication with the logic controller, the processing unit generating logic input signals in response to the plurality of safety related test scenarios, the processing unit providing the logic input signals to the logic controller, the logic input signals being representative of respective signals output by safety devices in the automation manufacturing process;
(c) triggering an execution of the plurality of safety related test scenarios via the safety logic code in response to processing unit providing the logic input signals to the logic controller;
(d) generating response output signals from the logic controller in response to the safety related test scenarios being executed by the safety logic code, each of the response output signals being representative of signals output from the logic controller to respective actuators in the manufacturing automation system; and
(e) determining a compliancy of the safety logic code by evaluating response output signals and associated logic input signals to a predetermined standard.

2. The method of claim 1 wherein the plurality of safety related test scenarios are generated by a test scenario generator, the plurality safety related test scenarios are provided from the test scenario generator to the processing unit.

3. The method of claim 2 wherein a test script is provided to the test scenario generator for generating the plurality of safety related test scenarios.

4. The method of claim 3 wherein input signals generated by a test bed are further provided to the processing unit, the test bed including at least one hardware device for generating the input signals provided to the processing unit, the at least one hardware device being representative of respective devices in a respective manufacturing automation system.

5. The method of claim 3 wherein the test bed is software-based for simulating respective hardware devices in a respective manufacturing automation system, the software-based test bed generating the signals to the processing unit emulates signals typically provided by the respective hardware devices.

6. The method of claim 1 wherein the processing unit generates the logic input signals in a format configured for triggering execution of the safety related test scenarios in the logic controller.

7. The method of claim 1 wherein the response output signals are recorded in a compiler.

8. The method of claim 7 wherein the compiler maps respective output response signals to respective logic input signals.

9. The method of claim 8 wherein the compiled response output signals and logic input signals are provided to a certification program for determining whether the safety logic code is in compliance with the predetermined standard.

10. The method of claim 7 further comprising the steps of storing the compiled response output signals and logic input signals in a database.

11. The method of claim 7 wherein the certification program determines a pass/fail status for each safety related test scenario in response to evaluating the compiled response output signals and logic input signals to the predetermined standard.

12. The method of claim 11 further comprising the steps of generating a certification report in response to determining the pass/fail status of each safety related test scenario.

13. The method of claim 1 wherein the logic controller executes a single safety related test scenario as a time dependent operation.

14. The method of claim 1 wherein the logic controller executes a plurality of interactive safety related test scenarios as a time dependent operation.

15. A computer-aided safety logic certification system for certifying safety logic code in a manufacturing automation system, the system comprising:
a logic controller for executing safety related test scenarios via the safety logic code in the manufacturing automation system, the logic controller generating response output signals in response to executing the safety related test scenarios;
a processing unit configured to communicate with the logic controller, the processing unit generating logic input signals and selectively providing the logic input signals to the logic controller for executing the safety related test scenarios via safety logic code; and
a certification program for determining a compliancy of the safety logic code by evaluating response output signals and associated logic input signals with a predetermined standard.

16. The system of claim 15 further comprising a scenario generator for generating the safety related test scenarios.

17. The system of claim 15 further comprising a compiler for mapping the response output signals to associated logic input signals.

18. The system of claim 17 further comprising database for storing the mapped response output signals and logic input signals.

19. The system of claim 18 further comprising a report generator for generating a certification report in response to determining the pass/fail status of each safety related test scenario.

20. The system of claim 19 further comprising a test bed for providing input signals to the processing unit, the test bed including at least one hardware device for generating the input signals provided to the processing unit, the at least one hardware device being representative of respective devices in a respective manufacturing automation system.

21. The system of claim 19 further comprising a test bed for providing input signals to the processing unit, the test bed including software for generating the input signals to the processing unit, the software emulating signals typically provided by the respective hardware devices in a respective manufacturing automation system.

22. A method of certifying safety logic in a manufacturing automation system having a logic controller for controlling safety functions, the logic controller receiving logic input signals and outputting output response signals, the method comprising the steps of:
(a) providing a test script;
(b) generating a plurality of safety related test scenarios for testing safety logic code in the logic controller, the plurality of safety related test scenarios being generated by a test scenario generator based on the test script;
(c) assembling a test-bed for generating input signals relating to the operation of the manufacturing automation system, the test bed including at least one hardware device for generating the input signals to a processing unit, the at least one hardware device representative of respective devices in a respective manufacturing automation system;
(d) configuring a processing unit for communication with the logic controller, the processing unit receiving the safety related test scenarios from the test scenario generator and the input signals from the test bed for generating the logic input signals, the logic input signals being provided from the processing unit to the logic controller;
(e) triggering the execution of the plurality of safety related test scenarios via the safety logic code in response to the logic input signals being provided from the processing unit to the logic controller;
(f) generating the response output signals by the logic controller in response to the safety related test scenarios being executed by the safety logic code, each of the response output signals being representative of signals output from the logic controller to respective actuators in the manufacturing automation system;
(g) recording the response output signals and associated input logic signals in a compiler; and
(h) determining a compliancy of the safety logic code by evaluating response output signals and associated input logic signals to a predetermined standard.
